(19) United States
(12) Patent Application Publication
(10) Pub. No.: US 2025/0299751 A1
(43) Pub. Date: Sep. 25, 2025

(54) SEMICONDUCTOR MEMORY DEVICE AND CONTROL METHOD OF SEMICONDUCTOR MEMORY DEVICE

(71) Applicant: Kioxia Corporation, Tokyo (JP)

(72) Inventors: Rina KAWAZOE, Yokohama Kanagawa (JP); Takuya KUSAKA, Kawasaki Kanagawa (JP); Daisuke ARIZONO, Yokohama Kanagawa (JP)

(21) Appl. No.: 19/056,629

(22) Filed: Feb. 18, 2025

(30) Foreign Application Priority Data
Mar. 21, 2024 (JP) 2024-045415

(51) Int. Cl. G11C 16/34; G11C 16/04; G11C 16/10; G11C 16/26

(52) U.S. Cl. CPC G11C 16/3404; G11C 16/0483; G11C 16/10; G11C 16/26; G11C 16/3459

(57) ABSTRACT

A semiconductor memory device includes a memory cell array including memory cells, word lines connected to the cells, bit lines connected to the cells, and a control circuit configured to execute, in response to a command sequence for writing data into a first memory cell connected to a first word line, a loop one or more times, each loop including a program operation for writing data into the first memory cell and a verification operation for verifying the data. The sequence indicates a level of a threshold voltage to be set to a second memory cell connected to a second word line adjacent to the first word line. The control circuit is configured to, after exiting the loop, determine whether to execute an operation to adjust a threshold voltage of the first memory cell based on the level of the threshold voltage to be set in the second memory cell.

### CROSS-REFERENCE TO RELATED APPLICATION

This application is based upon and claims the benefit of priority from Japanese Patent Application No. 2024-045415, filed Mar. 21, 2024, the entire contents of which are incorporated herein by reference.

### FIELD

Embodiments described herein relate generally to a semiconductor memory device and a control method of a semiconductor memory device.

### BACKGROUND

Recently, a NAND memory is widely used as a semiconductor memory device. In this semiconductor memory device, when data is written into a memory cell via a word line WLn+1 after writing data into a memory cell via a word line WLn, neighbor word-line interference (NWI) occurs, i.e., a threshold voltage of each of memory cells of the word line WLn in which the write operation has already completed increases.

Due to the effect of the NWI, a threshold voltage distribution of each of the memory cells of the word line WLn becomes wider. As a result, a margin between threshold voltage distributions decreases, and a fail bit count (FBC) increases. The effect of the NWI increases as the gap between gates decreases to increase memory cell density, and as multi-value writing progresses to higher number of bits.

### BRIEF DESCRIPTION OF THE DRAWINGS

FIG. 1 is a block diagram illustrating an example of a configuration of a memory system.

FIG. 2 is a block diagram illustrating an example of a configuration of a nonvolatile memory in FIG. 1.

FIG. 3 is a diagram illustrating a configuration example of a block of a memory cell array having a three-dimensional structure.

FIG. 4 is a block diagram illustrating an example of a configuration of a sense amplifier unit group and a data register in FIG. 2.

FIG. 5 is a circuit diagram illustrating an example of a specific configuration of a sense amplifier unit in FIG. 4.

FIG. 6 is a diagram illustrating 2-3-2 coding as an example of coding.

FIG. 7 is a diagram illustrating an example of a basic command sequence when data is written.

FIG. 8 is a diagram illustrating an example of voltage changes of a bit line and a selected word line during a program operation.

FIG. 9 is a diagram illustrating an example of a write sequence of A to G states.

FIG. 10 is a flowchart illustrating an operation of the memory system according to an embodiment.

FIG. 11 is a diagram illustrating a change of a threshold voltage distribution depending on the operation.

### DETAILED DESCRIPTION

Embodiments provide a semiconductor memory device and a control method of a semiconductor memory device in which spread of a threshold voltage distribution can be reduced even when affected by NWI.

In general, according to one embodiment, a semiconductor memory device comprises a memory cell array including a plurality of memory cells; a plurality of word lines connected to gates of the plurality of memory cells; a plurality of bit lines connected to first ends of the plurality of memory cells; and a control circuit configured to execute, in response to a command sequence for writing data into a first memory cell connected to a first word line, a loop one or more times, each loop including a first program operation for writing data into the first memory cell and a verification operation for verifying the data written in the second memory cell. The command sequence includes threshold voltage information about a level of a threshold voltage to be set in a second memory cell that is connected to a second word line adjacent to the first word line. The control circuit is configured to, after exiting the loop, determine whether to execute an operation to adjust a threshold voltage of the first memory cell based on the level of the threshold voltage to be set in the second memory cell.

Hereinafter, embodiments will be described in detail with reference to the drawings.

In one embodiment, when data is written into a memory cell of a word line WLn, data to be written into a memory cell of a word line WLn+1 is checked in advance, and a threshold of the data to be written into the memory cell of the word line WLn is adjusted according to a data pattern of the data to reduce the effect of NWI.

### Configuration of Memory System

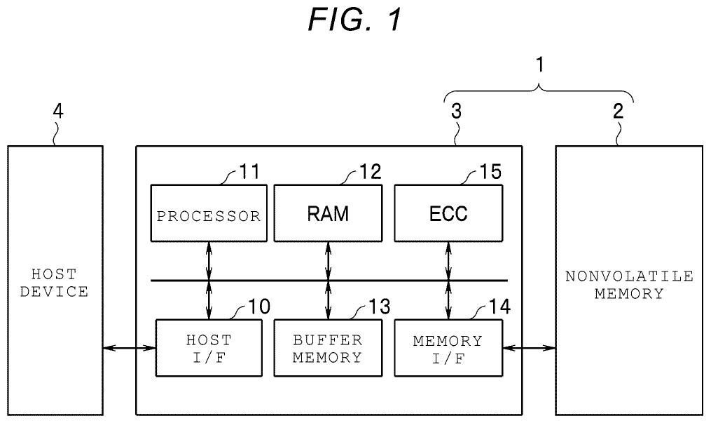

FIG. 1 is a block diagram illustrating a configuration of a memory system 1 according to one embodiment. The memory system 1 includes a nonvolatile memory 2 and a memory controller 3. The nonvolatile memory 2 may include a plurality of memory chips. The memory system 1 can be connected to a host device 4. The host device 4 is, for example, an electronic apparatus such as a personal computer or a mobile terminal.

The memory system 1 may have a configuration in which a plurality of chips forming the memory system 1 are mounted on a motherboard on which the host device 4 is mounted, or may be configured as a system large-scale integrated circuit (LSI) or a system-on-a-chip (SoC) where the memory system 1 is implemented with one module. Examples of the memory system 1 include a memory card such as an SD card, a solid-state-drive (SSD), and an embedded-multi-media-card (eMMC).

The nonvolatile memory 2 is a NAND memory including a plurality of memory cells and stores data in a nonvolatile manner. A configuration of the nonvolatile memory 2 will be described below.

The memory controller 3 commands to write (also referred to as “program”), read, or erase data into or from the nonvolatile memory 2, for example, in response to a command from the host device 4. In addition, the memory controller 3 manages a memory space of the nonvolatile memory 2. The memory controller 3 includes a host interface (host I/F) circuit 10, a processor 11, a random access memory (RAM) 12, a buffer memory 13, a memory interface circuit (memory I/F) circuit 14, an error checking and correcting (ECC) circuit 15, and the like.

The host I/F circuit 10 is connected to the host device 4 via a host bus and executes interface processing with the host device 4. In addition, the host I/F circuit 10 transmits and receives a command, an address, and data to and from the host device 4.

The processor 11 is, for example, a central processing unit (CPU). The processor 11 controls an overall operation of the memory controller 3. For example, when a write command is received from the host device 4, the processor 11 issues a write command corresponding to the write command from the host device 4 to the nonvolatile memory 2 via the memory I/F circuit 14. The same can be applied to the read command and the erase command. In addition, the processor 11 executes various processes such as wear leveling for managing the nonvolatile memory 2.

The RAM 12 is used as a work area of the processor 11 and stores, for example, firmware data loaded from the nonvolatile memory 2 or various tables generated by the processor 11. The RAM 12 is, for example, a DRAM or an SRAM.

The buffer memory 13 temporarily stores data transmitted from the host device 4, and temporarily stores data transmitted from the nonvolatile memory 2.

The memory I/F circuit 14 is connected to the nonvolatile memory 2 via a bus, and executes interface processing with the nonvolatile memory 2. In addition, the memory I/F circuit 14 transmits and receives a command, an address, and data to and from the nonvolatile memory 2.

When data is written, the ECC circuit 15 generates an error-correcting code for the write data, adds the error-correcting code to the write data, and transmits the data to the memory I/F circuit 14. In addition, when the data is read, the ECC circuit 15 executes error detection and/or error correction on the read data using the error-correcting code in the read data. The ECC circuit 15 may be provided in the memory I/F circuit 14.

### Configuration of Nonvolatile Memory

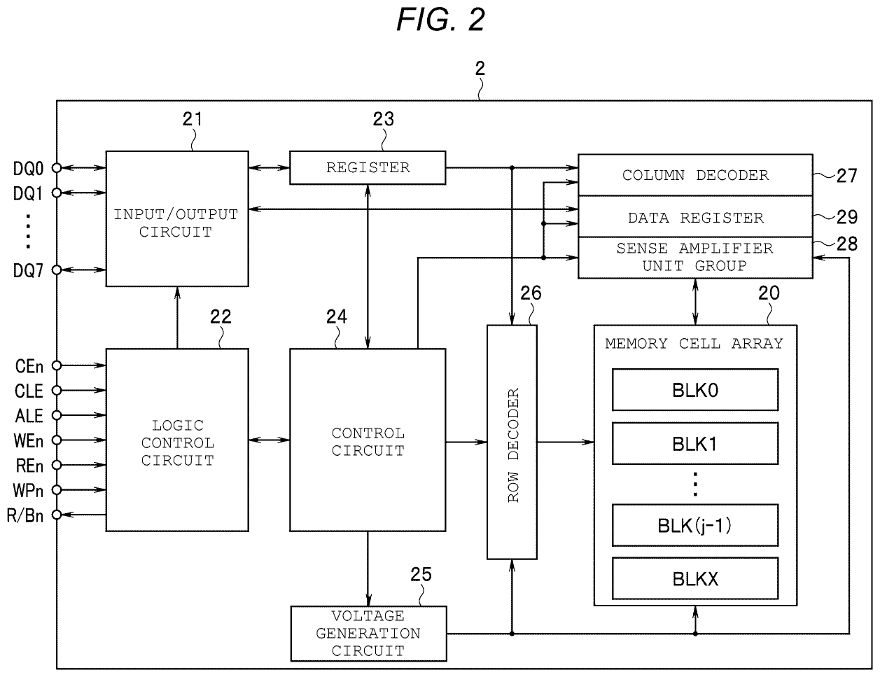

FIG. 2 is a block diagram illustrating an example of a configuration of the nonvolatile memory 2 in FIG. 1. The nonvolatile memory 2 includes a memory cell array 20, an input/output circuit 21, a logic control circuit 22, a register 23, a control circuit 24, a voltage generation circuit 25, a row decoder 26, a column decoder 27, a sense amplifier unit group 28, and a data register (or data cache) 29.

The memory cell array 20 includes a “j” number of blocks BLK0 to BLK(j−1) and a block BLKX. “j” represents an integer of 1 or more. Each of the blocks BLK includes a plurality of memory cell transistors. The memory cell transistor is an electrically writable memory cell. In the memory cell array 20, a plurality of bit lines BL, a plurality of word lines WL, a source line CELSRC, and the like are provided in order to control voltages that are applied to the memory cell transistors. A configuration of the block BLK will be described below.

The input/output circuit 21 and the logic control circuit 22 are connected to the memory controller 3 via a bus. The input/output circuit 21 transmits and receives the signals DQ (for example, DQ0 to DQ7) to and from the memory controller 3 via the bus.

The logic control circuit 22 receives external control signals (for example, a chip enable signal CEn, a command latch enable signal CLE, an address latch enable signal ALE, a write enable signal WEn, a read enable signal REn, and a write-protection signal WPn) from the memory controller 3 via the bus. “n” added to the signal name represents active-low. In addition, the logic control circuit 22 transmits a ready/busy signal R/Bn to the memory controller 3 via the bus.

In a system configuration where a plurality of the nonvolatile memories 2 are used, the chip enable signal CEn is a signal for selecting and enabling a specific nonvolatile memory 2. The chip enable signal CLE can latch a command to be transmitted as the signal DQ in the register 23. The address latch enable signal ALE can latch an address to be transmitted as the signal DQ in the register 23. The write enable signal WEn enables writing. The read enable signal REn enables reading. The write-protection signal WPn prevents writing and erasing. When a basic operation command is used, the ready/busy signal R/Bn represents whether the nonvolatile memory 2 is in a ready state (i.e., a state where the nonvolatile memory 2 can receive a command from an external apparatus) where write, read, and an erase operations are not executed or in a busy state (i.e., a state where the nonvolatile memory 2 cannot receive a command from an external apparatus).

The register 23 includes a command register, an address register, and a status register. The command register temporarily stores a command. The address register temporarily stores an address. The status register temporarily stores data required for the operation of the nonvolatile memory 2. The register 23 is, for example, an SRAM.

The control circuit 24 receives a command from the register 23 and integrally controls the nonvolatile memory 2 in accordance with a sequence based on this command.

The voltage generation circuit 25 uses a power supply voltage applied from the outside of the nonvolatile memory 2 to generate a plurality of voltages required for a write operation, a read operation, and an erase operation. The voltage generation circuit 25 applies the plurality of generated voltages to the memory cell array 20, the row decoder 26, the sense amplifier unit group 28, and the like, respectively.

The row decoder 26 receives a row address from the register 23 and decodes the received row address. The row decoder 26 executes a selection operation of a word line based on the decoded row address. A word line connected to the memory cell transistor MT as a write or read target will be referred to as a selected word line. The row decoder 26 applies a plurality of voltages required for a write operation, a read operation, and an erase operation to the selected block BLK.

The column decoder 27 receives a column address from the register 23 and decodes the received column address. The column decoder 27 applies a predetermined voltage to each of the bit lines BL based on the decoded column address.

The sense amplifier unit group 28 detects and amplifies data read from the memory cell transistor MT to the bit line BL when the data is read. In addition, when the data is written, the sense amplifier unit group 28 applies a voltage for writing data to the bit line BL.

When the data is read, the data register 29 temporarily stores the data transmitted from the sense amplifier unit group 28 and serially transmits the data to the input/output circuit 21. In addition, when data is written, the data register 29 temporarily stores the data that is serially transmitted from the input/output circuit 21 and transmits the data to the sense amplifier unit group 28. The data register 29 is, for example, an SRAM.

### Block Configuration of Memory Cell Array

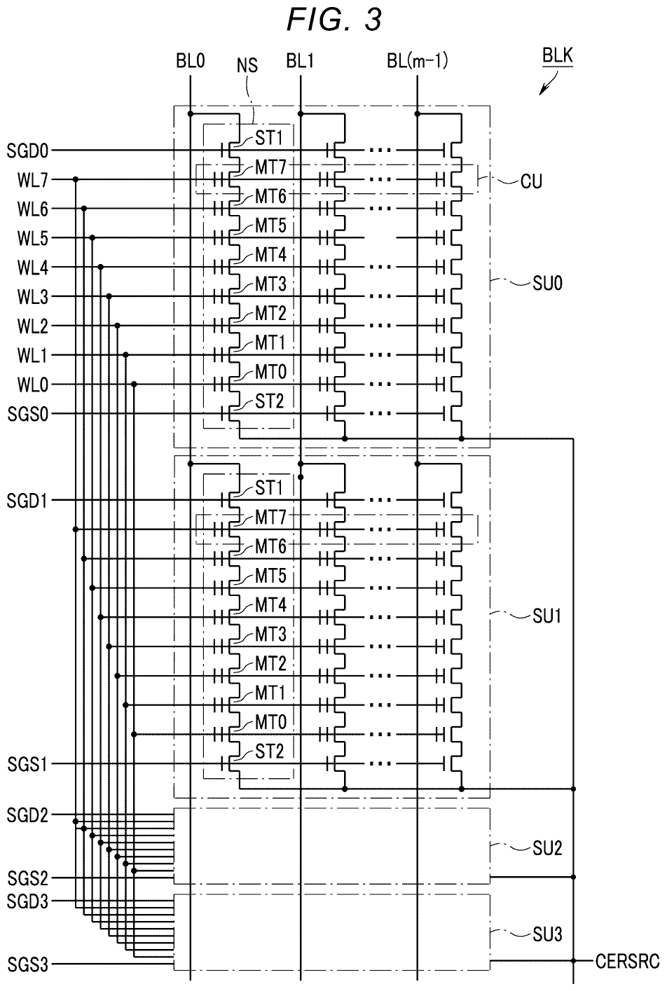

FIG. 3 is a diagram illustrating a configuration example of a block of the memory cell array 20 having a three-dimensional structure. FIG. 3 illustrates one block BLK among a plurality of blocks configuring the memory cell array 20. Other blocks of the memory cell array have the same configuration as that of FIG. 3.

As illustrated in the drawing, the block BLK includes, for example, four string units SU0 to SU3 (hereinafter, representatively referred to as “string units SU”). In addition, each of the string units SU includes a NAND string NS including a plurality of memory cell transistors MT (MT0 to MT7) and select gate transistors ST1 and ST2. Here, the number of memory cell transistors MT in the NAND string NS is eight in FIG. 3 but may be more than eight. The select gate transistors ST1 and ST2 are illustrated as one transistor on the electric circuit and may have the same structure as that of the memory cell transistor. In addition, a plurality of select gate transistors may be used as the select gate transistors ST1 and ST2. Further, a dummy cell transistor may be provided between the memory cell transistors MT and the select gate transistors ST1 and ST2.

The memory cell transistors MT are arranged between the select gate transistors ST1 and ST2 such that the transistors are connected in series. A memory cell transistor MT7 on a first end side (i.e., a bit line side) is connected to the select gate transistor ST1, and a memory cell transistor MT0 on a second end side (i.e., a source line side) is connected to the select gate transistor ST2.

Gates of the respective select gate transistors ST1 of the string units SU0 to SU3 are connected to select gate lines SGD0 to SGD3 (hereinafter, representatively referred to as “select gate lines SGD”), respectively. In addition, gates of the respective select gate transistors ST2 of the string units SU0 to SU3 are connected to select gate lines SGS0 to SGS3 (hereinafter, representatively referred to as “select gate lines SGS”), respectively. Gates of a plurality of select gate transistor ST2 in each of the blocks BLK may be connected to the common select gate line SGS.

Gates of the memory cell transistors MT0 to MT7 in the same block BLK are connected in common to word lines WL0 to WL7, respectively. That is, the word lines WL0 to WL7 are connected in common between the plurality of string units SU0 to SU3 in the same block BLK. On the other hand, the select gate lines SGD are independent from each other for each of the string units SU0 to SU3 even in the same block BLK. Gates of memory cell transistors MTi on the same line in the block BLK are connected to the same word line WLi.

Each of the NAND strings NS is connected to the corresponding bit line. Accordingly, each of the memory cell transistors MT is connected to the bit line through the select gate transistors ST1 and ST2 in the NAND string NS or another memory cell transistor MT. In general, data of the memory cell transistors MT in the same block BLK is collectively erased. On the other hand, typically, reading and writing of data are collectively executed on a plurality of memory cell transistors MT that are connected in common to one word line WL provided in one string unit SU. This set including memory cell transistors MT that share the word line WL in one string unit SU will be referred to as “cell unit CU”.

That is, the write operation on the cell unit CU is executed in units of pages. For example, when each of the cells is a triple level cell (TLC) capable of storing 3-bit or octal data, one cell unit CU can store data corresponding to three pages. Three bits that can be stored in each of the memory cell transistors MT correspond to the three pages.

### Configuration of Sense Amplifier Unit and Data Register

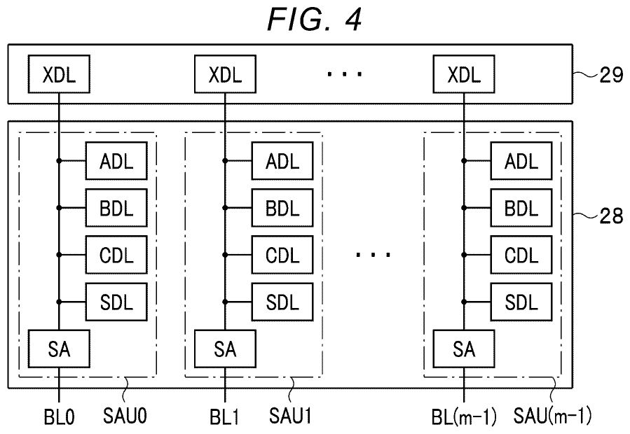

FIG. 4 is a block diagram illustrating an example of a configuration of the sense amplifier unit group 28 and the data register 29 in FIG. 2.

The sense amplifier unit group 28 includes sense amplifier units SAU0 to SAU(m−1) (hereinafter, representatively referred to as the sense amplifier units SAU) corresponding to bit lines BL0 to BL(m−1). Each of the sense amplifier units SAU includes a sense amplifier SA and data latch circuits SDL, ADL, BDL, and CDL. The sense amplifier SA and the data latch circuits SDL, ADL, BDL, and CDL are connected such that data can be transmitted between each other.

The data latch circuits SDL, ADL, BDL, and CDL temporarily store data. During the write operation, the sense amplifier SA controls a voltage of the bit line BL according to the data stored by the data latch circuit SDL. The data latch circuits ADL, BDL, and CDL are used for a multi-level operation where the memory cell transistor MT stores data of 2 bits or more. That is, the data latch circuit ADL is used to store write data of a Lower page. The data latch circuit BDL is used to store write data of a Middle page. The data latch circuit CDL is used to store write data of an Upper page. The number of data latch circuits in the sense amplifier unit SAU is determined depending on the number of bits stored in one memory cell transistor MT.

During the read operation, the sense amplifier SA detects the data read to the corresponding bit line BL, and determines whether the data is 0 data or 1 data. In addition, during the write operation, the sense amplifier SA applies a voltage to the bit line BL based on the write data.

The data register 29 includes data latch circuits XDL of a number corresponding to the sense amplifier units SAU0 to SAU(m−1). The data latch circuit XDL is connected to the input/output circuit 21. The data latch circuit XDL temporarily stores write data transmitted from the input/output circuit 21, and temporarily stores read data transmitted from the sense amplifier unit SAU. More specifically, data transmission between the input/output circuit 21 and the sense amplifier unit group 28 is executed via the data latch circuits XDL corresponding to one page. The write data received by the input/output circuit 21 is transmitted to any of the data latch circuits ADL, BDL, and CDL via the data latch circuit XDL. The read data read by the sense amplifier SA is transmitted to the input/output circuit 21 via the data latch circuit XDL.

In addition, as described below, when data is written into the memory cell of the word line WLn, the data latch circuit XDL stores threshold information corresponding to the data pattern of the word line WLn+1.

### Sense Amplifier Circuit

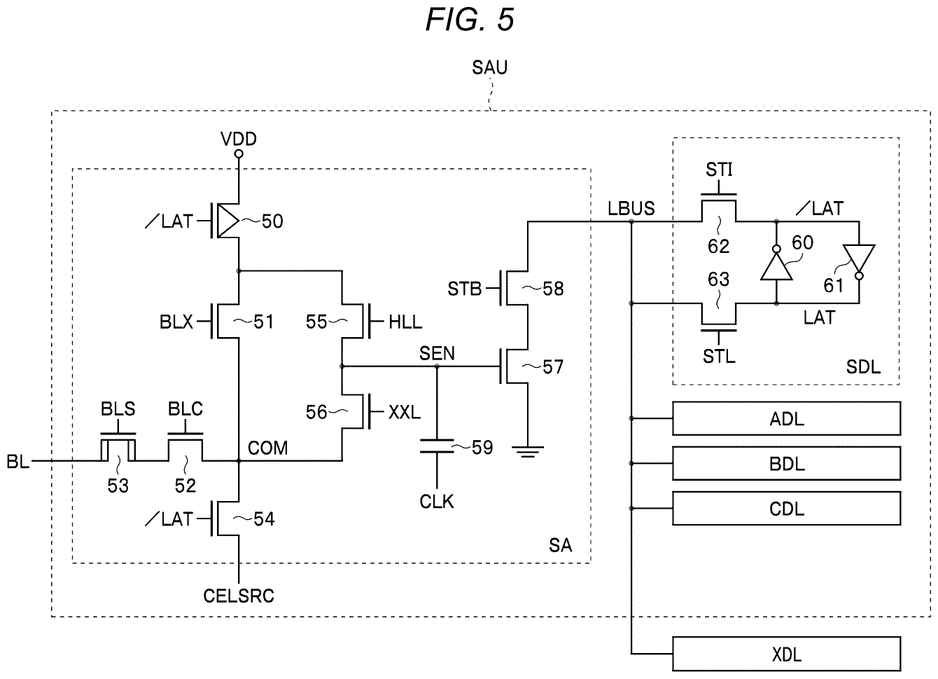

FIG. 5 is a circuit diagram illustrating an example of a specific configuration of the sense amplifier unit SAU in FIG. 4.

As illustrated in FIG. 5, the sense amplifier unit SAU includes the sense amplifier SA and data latch circuits SDL, ADL, BDL, and CDL. The sense amplifier SA and the data latch circuits SDL, ADL, BDL, CDL, and XDL are connected such that data can be received between each other via a bus LBUS.

The data latch circuit SDL includes, for example, inverters 60 and 61 and n-channel MOS transistors 62 and 63. An input node of the inverter 60 and an output node of the inverter 61 are connected to a node LAT. An input node of the inverter 61 and an output node of the inverter 60 are connected to a node/LAT. Data of the nodes/LAT and LAT is stored by the inverters 60 and 61. The write data is supplied to the node LAT. The data stored in the node/LAT is inverted data of the data stored in the node LAT.

A first end of a drain-source path of the transistor 62 is connected to the node/LAT, and a second end thereof is connected to the bus LBUS. In addition, a first end of a drain-source path of the transistor 63 is connected to the node LAT, and a second end thereof is connected to the bus LBUS. A control signal STL is input to a gate of the transistor 63, and a control signal ST1 is input to a gate of the transistor 62.

Since circuit configurations of the data latch circuits ADL, BDL, CDL, and XDL are the same as that of the data latch circuit SDL, the description thereof will not be repeated. Various control signals supplied to the sense amplifier unit SAU are supplied from the control circuit 24.

The sense amplifier SA includes, for example, a p-channel MOS transistor 50, n-channel MOS transistors 51 to 58, and a capacitor 59.

During the read operation, the sense amplifier SA senses data read to the corresponding bit line BL, and determines whether the read data is “0” or “1”. In addition, during a program operation, the sense amplifier SA sets a voltage value corresponding to the data “0” or “1” to be written into the corresponding bit line BL.

In the sense amplifier SA, the program operation relates to transistors 50 to 54. Between a power supply line through which a voltage VDD as an internal power supply voltage is applied and a node COM, a source-drain path of the transistor 50 as a second transistor and a drain-source path of the transistor 51 are connected in series. In addition, between the node COM and a node CELSRC that supplies a voltage VSS as a ground voltage, a drain-source path of a transistor 54 as a third transistor is connected. In addition, between the node COM and the bit line BL, a drain-source path of the transistor 52 as a first transistor and a drain-source path of the transistor 53 are connected in series.

Gates of the transistors 50 and 54 are connected to the node/LAT. Accordingly, when the node LAT corresponding to the “0” data is at a low level (hereinafter referred to as the L level), the node/LAT is maintained at a high level (hereinafter, referred to as the H level), the transistor 50 is turned off, and the transistor 54 is turned on. Conversely, when the node LAT corresponding to the “1” data is at the H level, the node/LAT is maintained at the L level, the transistor 50 is turned on, and the transistor 54 is turned off.

During the program operation, control signals HLL and XXL supplied to gates of the transistors 55 and 56 are at the L level, and the transistors 55 and 56 are turned off. A control signal BLX supplied to the transistor 51 is at the H level, and the transistor 51 is turned on. In addition, during the typical program operation, the transistors 52 and 53 are electrically connected by the control signals BLC and BLS.

Accordingly, when “O” data is stored in the node LAT, the transistor 50 is turned off, the transistor 54 is turned on, and a bit line voltage such as the voltage VSS (for example, 0 V) is applied from the node CELSRC to the bit line BL. In addition, when “1” data is stored in the node LAT, the transistor 50 is turned on, the transistor 54 is turned off, and for example, a bit line voltage such as 2.5 V is applied to the bit line BL according to the control signals BLC and BLS applied to the transistors 52 and 53.

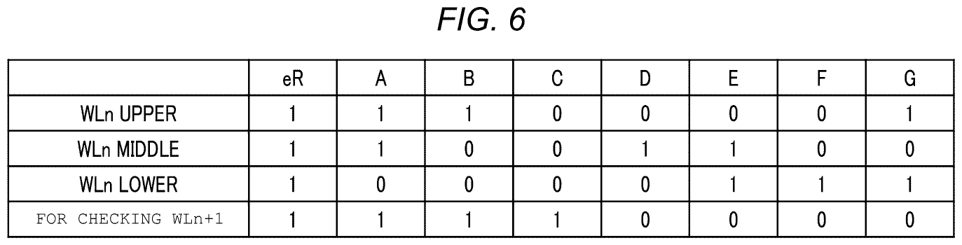

FIG. 6 is a diagram illustrating 2-3-2 coding as an example of coding. FIG. 6 illustrates values of an UPPER bit, a MIDDLE bit, and a LOWER bit of data for each of threshold voltage distributions.

In the example of FIG. 6, the memory cell transistor of the Er state stores data (1,1,1), the memory cell transistor of the A state stores data (1,1,0), the memory cell transistor of the B state stores data (1,0,0), the memory cell transistor of the C state stores data (0,0,0), the memory cell transistor of the D state stores data (0,1,0), the memory cell transistor of the E state stores data (0,1,1), the memory cell transistor of the F state stores data (0,0,1), and the memory cell transistor of the G state stores data (1,0,1).

Not only the data to be written into the memory cell of the word line WLn but also threshold information corresponding to the data pattern to be written into the memory cell of the word line WLn+1 are transmitted to the data latch circuit XDL. The data pattern to be written into the memory cell of the word line WLn+1 is binarized into a “high” threshold and a “low” threshold. For example, when the data pattern to be written into the memory cell of the word line WLn+1 is in the Er state to the C state, the threshold is determined to be “low”, and when the data pattern to be written into the memory cell of the word line WLn+1 is in the D state to the G state, the threshold is determined to be “high”. When the threshold of the data to be written into the memory cell of the word line WLn+1 is “low”, “1” is input as the threshold information, and when the threshold of the data to be written into the memory cell of the word line WLn+1 is “high”, “O” is input as the threshold information. The threshold information is calculated by the memory controller 3 based on the data pattern to be written into the memory cell of the word line WLn+1. The data pattern to be written into the memory cell of the word line WLn+1 may be temporarily stored in the memory cell of the memory cell array 20 such that the control circuit 24 of the nonvolatile memory 2 calculates the threshold information based on the stored data pattern. In addition, the control circuit 24 may temporarily store the calculated threshold information in the memory cell.

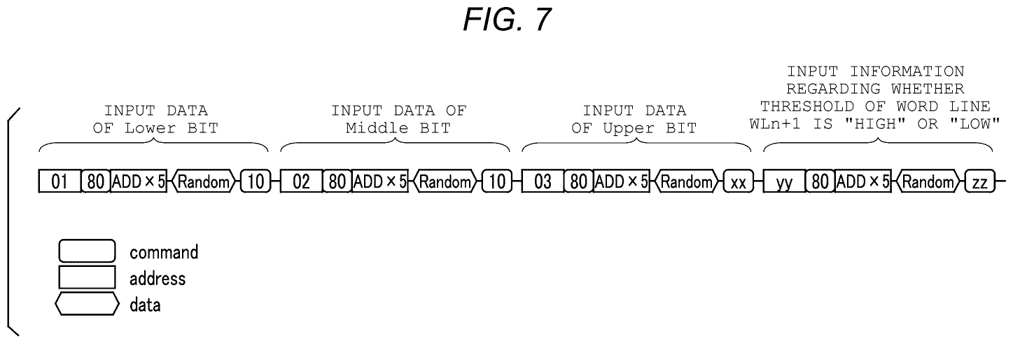

The threshold information corresponding to the data pattern of the word line WLn+1 is input by a command sequence illustrated in FIG. 7. FIG. 7 is a diagram illustrating an example of a basic command sequence when data is written.

As illustrated in FIG. 7, in a command sequence, data of the Lower bit, data of the Middle bit, and data of the Upper bit are input in this order. After inputting the data of the Upper bit, threshold information representing whether the threshold of the word line WLn+1 is “high” or “low” is input.

As described above, the data of the Lower bit, the data of the Middle bit, and the data of the Upper bit are temporarily stored in the data latch circuit XDL, and are transmitted to the data latch circuits ADL, BDL, and CDL, respectively.

Therefore, when data is written, after the write data is transmitted from the data latch circuit XDL to the data latch circuits ADL, BDL, and CDL, the data latch circuit XDL is in a free state without being used. Accordingly, after inputting the data of the Upper bit, the threshold information of the word line WLn+1 is input, and the threshold information of the word line WLn+1 is stored in the data latch circuit XDL in the free state (i.e., unused). As a result, in order to store the threshold information of the word line WLn+1, a new data latch circuit does not need to be provided, and the circuit size does not increase.

In one embodiment, when data is written into a memory cell via the word line WLn that is the selected word line as a write target, whether to apply a weak program pulse is determined based on threshold information of the word line WLn+1 that is an adjacent word line adjacent to the word line WLn, and the threshold for writing the data into the word line WLn is adjusted.

The application of the weak program pulse is executed by adjusting the voltage of the bit line BL during a quick pass write (QPW) operation. In the QPW operation, for example, a voltage that is higher than the “L” level (the ground voltage Vss, for example, 0 V) and is lower than the “H” level (the write-inhibit voltage Vdd, for example, 2.5 V) is applied to the bit line BL corresponding to the memory cell where the threshold is desired to be increased with a small variation width. As a result, in the QPW operation, three types of controls including a control of increasing the threshold, a control of maintaining the threshold, and a control of increasing the threshold with a small variation width are executed on a plurality of memory cells in a memory cell group.

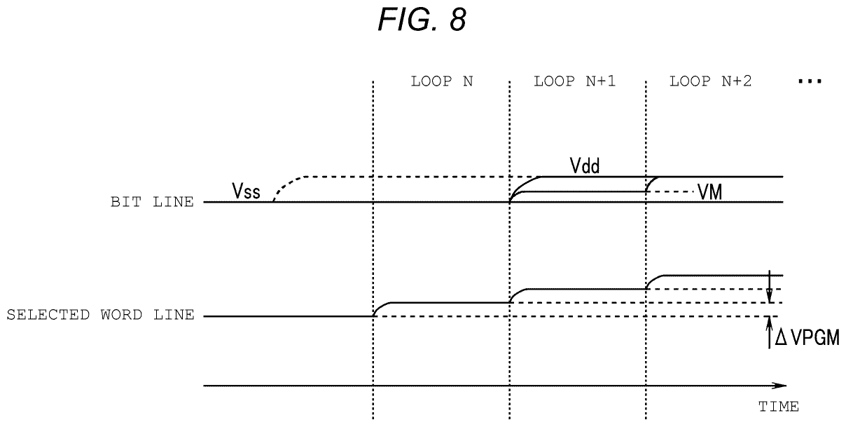

FIG. 8 is a diagram illustrating an example of voltage changes of a bit line and a selected word line during a program operation.

During a program operation (i.e., a write operation), the ground voltage Vss is applied to a bit line BL connected to a memory cell where writing is not completed. In addition, during the program operation, a program voltage VPGM is applied to the selected word line. The program voltage VPGM increases stepwise with a predetermined voltage width (AVPGM) as a loop progresses. A write pass voltage VPASS is applied to the non-selected word line. The write pass voltage VPASS is a voltage lower than the program voltage VPGM.

Here, a loop that is determined as verification pass is set as a loop N. In the next loop N+1 of the loop N, threshold information corresponding to the data pattern of the word line WLn+1 is checked. The voltage of the bit line BL that is adjacent to the memory cell of the word line WLn+1 having a high threshold and is connected to the memory cell of the word line WLn is increased to the write-inhibit voltage Vdd in the loop N+1 to prevent additional writing from occurring.

On the other hand, the voltage of the bit line BL that is adjacent to the memory cell of the word line WLn+1 having a low threshold and is connected to the memory cell of the word line WLn is slightly increased to a voltage Vm in the loop N+1 such that a voltage difference from the program voltage VPGM is reduced as compared to the loop N. As a result, a weak program pulse is applied. This way, by controlling the voltage to be applied to the bit line BL as in the QPW operation, the threshold can be increased with a small variation width. The voltage Vm is a voltage that is higher than the ground voltage Vss and lower than the write-inhibit voltage Vdd. As a result, by adding one loop to the number of loops in the typical program operation, the additional program operation (i.e., the application of the weak program pulse) can be implemented.

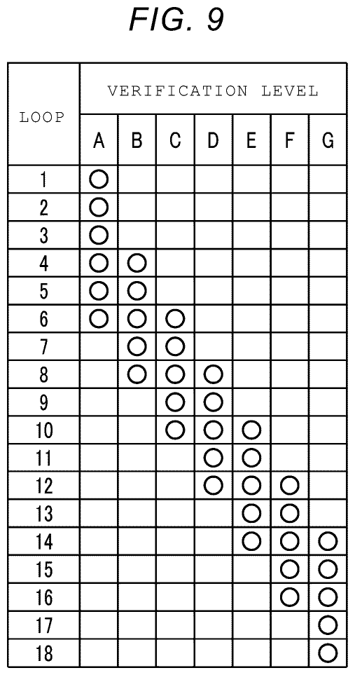

The description will be given in more detail. FIG. 9 is a diagram illustrating an example of a write sequence of A to G states. For example, it is assumed that a memory cell connected to the word line WLn is determined as verification pass having a threshold voltage A in the third loop. This memory cell is assumed as a memory cell M. A memory cell that is adjacent to the memory cell M and is connected to the word line WLn+1 is assumed as a memory cell X. At this time, in a conventional memory system, when a program voltage VPGM_4 is applied to the WLn in the fourth loop, the write-inhibit voltage Vdd is applied to the bit line B connected to the memory cell M irrespective of the threshold voltage to be written into the memory cell X. In the memory system 1, when the threshold voltage to be written into the memory cell X is low, the voltage Vm is applied to the bit line B to execute the weak write operation on the memory cell M. When the threshold voltage to be written into the memory cell X is high, the write-inhibit voltage Vdd is applied to the bit line B to prevent writing into the memory cell M.

It is assumed that a memory cell connected to the word line WLn is determined as verification pass having a threshold voltage G in the eighteenth loop that is the scheduled final loop. This memory cell is assumed as a memory cell N. A memory cell that is adjacent to the memory cell N and is connected to the word line WLn+1 is assumed as a memory cell Y. Since the eighteenth loop is the final loop, the weak write operation is not executed on the memory cell N in the nineteenth loop irrespective of the threshold voltage to be written into the memory cell Y.

This way, in the memory system 1, the number of loops is not further added to the scheduled number of loops, and thus, the write time is not increased.

Alternatively, in the nineteenth loop, the weak write operation corresponding to the threshold voltage to be written into the memory cell Y may be executed on the memory cell N.

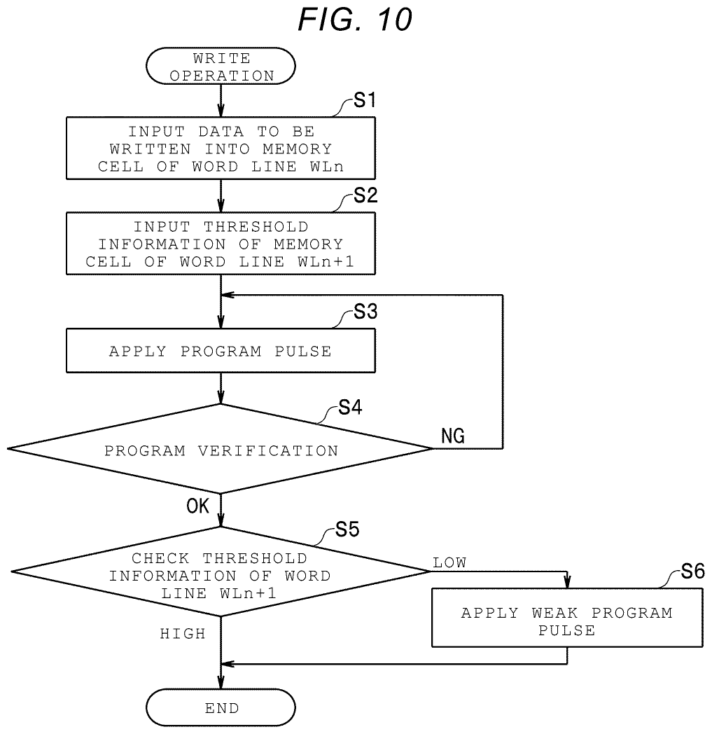

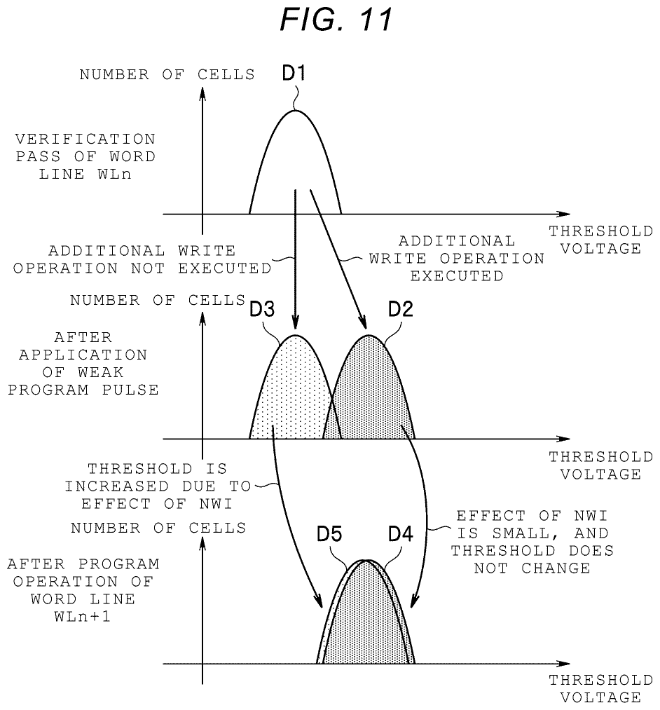

FIG. 10 is a flowchart illustrating an operation of the memory system 1. FIG. 11 is a diagram illustrating a change of a threshold voltage distribution depending on the operation.

First, data to be written is input to the memory cell of the word line WLn (S1). The data written into the memory cell of the word line WLn is transmitted to the data latch circuits ADL, BDL, and CDL via the data latch circuit XDL, and is stored in the data latch circuits ADL, BDL, and CDL. Next, threshold information of the memory cell of the word line WLn+1 is input (S2). The threshold information of the memory cell of the word line WLn+1 is stored in the unused data latch circuit XDL.

Next, the program pulse (i.e., the program voltage VPGM) is applied to a word line corresponding to a page as a write target (S3) to execute the program operation. After the program operation, a program verification of determining whether the threshold voltage reaches a desired target voltage is executed to determine whether the result of the program verification is verification pass or verification fail (S4).

When the result of the program verification is determined as verification fail (S4: NG), the process returns to S3, and the loop including the program operation and the program verification is executed multiple times. On the other hand, when the result of the program verification is determined as verification pass (S4: OK), the process proceeds to S5. A threshold voltage distribution D1 of FIG. 11 illustrates a threshold voltage distribution where the memory cell of the word line WLn is determined as verification pass.

Next, when the result of the program verification is determined as verification pass in the process of S4, the threshold information of the word line WLn+1 is checked (S5).

When the threshold of the memory cell of the word line WLn+1 is determined to be low based on the threshold information of the word line WLn+1, the weak program pulse is applied to the memory cell of the word line WLn (S6), and the process ends. On the other hand, when the threshold of the memory cell of the word line WLn+1 is determined to be high based on the threshold information of the word line WLn+1, the process ends as it is.

As illustrated in FIG. 11, when the weak program pulse is applied to execute the additional write operation, the threshold of the memory cell on which the additional write operation is executed increases. A threshold voltage distribution D2 illustrates a threshold voltage distribution of the memory cell on which the additional write operation is executed.

On the other hand, when the weak program pulse is not applied and the additional write operation is not executed, the threshold of the memory cell on which the additional write operation is not executed does not change. A threshold voltage distribution D3 illustrates a threshold voltage distribution of the memory cell on which the additional write operation is not executed. As a result, when the program operation of the word line WLn is completed, the threshold voltage distribution of the word line WLn is in a spread state.

When the program operation of the word line WLn is completed, the program operation of the word line WLn+1 is executed. When the threshold of the data to be written into the memory cell of the word line WLn+1 is low, the effect of NWI is small, and the threshold of the memory cell of the word line WLn does not substantially change. A threshold voltage distribution D4 illustrates a threshold voltage distribution of the memory cell of the word line WLn where the effect of NWI is small.

On the other hand, when the threshold of the data to be written into the memory cell of the word line WLn+1 is high, the threshold of the memory cell of the word line WLn increases due to the effect of NWI. A threshold voltage distribution D5 illustrates a threshold voltage distribution of the memory cell of the word line WLn where the threshold is high due to the effect of NWI.

This way, when the program operation of the word line WLn+1 is completed, the threshold of the memory cell of the word line WLn that is adjacent to the memory cell of the word line WLn+1 having a high threshold is increased due to the effect of NWI. As a result, when the program operation of the word line WLn+1 is completed, the threshold voltage distribution of the word line WLn is in a narrow state.

As described above, the threshold information corresponding to the data pattern of the word line WLn+1 is checked after the determination of verification pass, when the threshold is “high”, the process ends, and when the threshold is “low”, the weak program pulse is applied. Through this process, after the end of the write or program operation of the word line WLn+1, the threshold of the memory cell of the word line WLn to which the weak program pulse is not applied is increased due to the effect of NWI.

As a result, the threshold of the memory cell of the word line WLn is substantially the same between when the threshold of the memory cell of the word line WLn+1 is low and when the threshold of the memory cell of the word line WLn+1 is high. Therefore, the spread of the threshold voltage distribution or distribution thickness can be reduced. In addition, a margin between the threshold voltage distributions can be ensured, and thus an increase in fail bit count (FBC) can be prevented.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a memory cell array including a plurality of memory cells;
a plurality of word lines connected to gates of the plurality of memory cells;
a plurality of bit lines connected to first ends of the plurality of memory cells; and
a control circuit configured to execute, in response to a command sequence for writing data into a first memory cell connected to a first word line, a loop one or more times, wherein each loop includes a first program operation for writing data into the first memory cell and a verification operation for verifying the data written in the memory cell, wherein
the command sequence includes threshold voltage information about a level of a threshold voltage to be set in a second memory cell that is connected to a second word line adjacent to the first word line, and
the control circuit is configured to, after exiting the loop, determine whether to execute an operation to adjust a threshold voltage of the first memory cell based on the level of the threshold voltage to be set in the second memory cell.

2. The semiconductor memory device according to claim 1, wherein
the control circuit is configured to exit the loop upon determining that the data has been successfully written into the first memory cell.

3. The semiconductor memory device according to claim 1, wherein
the threshold voltage information indicates whether the level of the threshold voltage to be set to the second memory cell is high or low, and
the control circuit executes the operation to adjust the threshold voltage of the first memory cell when the threshold voltage information indicates that the level of the threshold voltage to be set to the second memory cell is low.

4. The semiconductor memory device according to claim 3, wherein
the control circuit does not execute the operation to adjust the threshold voltage of the first memory cell when the threshold voltage information indicates that the level of the threshold voltage to be set to the second memory cell is high.

5. The semiconductor memory device according to claim 3, wherein
the control circuit is configured to perform a second program operation on the first memory cell to increase the threshold voltage thereof.

6. The semiconductor memory device according to claim 5, further comprising:
a sense amplifier circuit configured to apply a bit line voltage to the plurality of bit lines, wherein
the sense amplifier circuit applies the bit line voltage of a first value during the first program operation and the bit line voltage of a second value during the second program operation, the second value being lower than the first value.

7. The semiconductor memory device according to claim 6, wherein
the second value is higher than a ground voltage value and is lower than a write-inhibit voltage value.

8. The semiconductor memory device according to claim 1, wherein
the control circuit is configured to generate the threshold voltage information based on a data pattern of data to be written into memory cells connected to the second word line.

9. The semiconductor memory device according to claim 8, wherein
the control circuit is configured to store information indicating the data pattern in the memory cell array.

10. The semiconductor memory device according to claim 1, wherein
the control circuit is configured to store the threshold voltage information in the memory cell array.

11. A control method performed by a semiconductor memory device that includes:
a memory cell array including a plurality of memory cells,
a plurality of word lines connected to gates of the plurality of memory cells, and
a plurality of bit lines connected to first ends of the plurality of memory cells, the control method comprising:
executing, in response to a command sequence for writing data into a first memory cell connected to a first word line, a loop one or more times, wherein each loop includes a first program operation for writing data into the first memory cell and a verification operation for verifying the data written in the memory cell, wherein
the command sequence includes threshold voltage information about a level of a threshold voltage to be set in a second memory cell that is connected to a second word line adjacent to the first word line, and
the control method further comprises, after exiting the loop, determining whether to execute an operation to adjust a threshold voltage of the first memory cell based on the level of the threshold voltage to be set in the second memory cell.

12. The control method according to claim 11, further comprising:
exiting the loop upon determining that the data has been successfully written into the first memory cell.

13. The control method according to claim 11, wherein
the threshold voltage information indicates whether the level of the threshold voltage to be set to the second memory cell is high or low, and
the threshold voltage of the first memory cell is adjusted when the threshold voltage information indicates that the level of the threshold voltage to be set to the second memory cell is low.

14. The control method according to claim 13, wherein
the threshold voltage of the first memory cell is not adjusted when the threshold voltage information indicates that the level of the threshold voltage to be set to the second memory cell is high.

15. The control method according to claim 13, wherein
adjusting includes performing a second program operation on the first memory cell to increase the threshold voltage thereof.

16. The control method according to claim 15, wherein
a bit line voltage of a first value is applied to the bit lines during the first program operation and a bit line voltage of a second value is applied to the bit lines during the second program operation, the second value being lower than the first value.

17. The control method according to claim 16, wherein
the second value is higher than a ground voltage value and is lower than a write-inhibit voltage value.

18. The control method according to claim 11, further comprising:
generating the threshold voltage information based on a data pattern of data to be written into memory cells connected to the second word line.

19. The control method according to claim 18, further comprising:
storing information indicating the data pattern in the memory cell array.

20. The control method according to claim 11, further comprising:
storing the threshold voltage information in the memory cell array.
